(19) United States
(12) Patent Application Publication
(10) Pub. No.: US 2007/0070608 A1
(43) Pub. Date: Mar. 29, 2007

(54) Packaged electronic devices and process of manufacturing same

(75) Inventors: Robert W. Warren, Newport Beach, CA (US); Steve X. Liang, San Diego, CA (US); Tony LoBianco, Irvine, CA (US); Gene Gan, Fremont, CA (US)

Correspondence Address: CROWELL & MORING LLP;INTELLECTUAL PROPERTY GROUP, P.O. BOX 14300, WASHINGTON, DC, 20044-4300, US

(73) Assignee: SKYWORKS SOLUTIONS, INC., Irvine, CA (US)

(21) Appl. No.: 11/242,431

(22) Filed: Sep. 29, 2005

(51) Int. Cl. H05K 7/00

(52) U.S. Cl. 361/735; 361/760

(57) ABSTRACT

An electronic module and a process for forming an electronic module are provided. Uniform and sealed air gaps are formed in a vertical direction between two or more electronic devices. The uniform and sealed air gaps are formed by arranging spacers between the electronic devices, where the height of the spacers is selected depending upon the operating characteristics of the particular type of electronic devices.

### BACKGROUND OF THE INVENTION

Today's semiconductor packages include a number of different electronic devices. These electronic devices can include, for example, integrated circuits (ICs), microelectronic machines (MEMs), and/or the like. The integration of different electronic devices into a device module typically requires a significant amount of horizontal space, and relatively high assembly and processing complexity and cost. Current techniques for integrating different electronic devices into a device module largely focus on minimizing two-dimensional (X,Y) area of the discrete electronic devices. The discrete devices are assembled separately into the modules, where each such module includes a separate lid. Additionally, the assembled discrete devices occupy at least as much area in the two-dimensional (X,Y) portion of the module as the combined two-dimension area of the individual devices.

### SUMMARY OF THE INVENTION

An electronic module and process for forming the same are provided. In accordance with exemplary embodiments of the present invention, a second electronic device is arranged above a first electronic device. Spacers are arranged between a first and second electronic device to form a uniform and sealed air gap between the electronic devices. The height of the spacers, and the resulting height of the air gap, is selected based upon the type of electronic device. For radio frequency electronic devices, the height of the spacers is selected to reduce radio frequency interference between the first and second electronic devices. In the case of microelectronic machines, the height is selected to allow sufficient clearance for operation of the machines.

Other objects, advantages and novel features of the present invention will become apparent from the following detailed description of the invention when considered in conjunction with the accompanying drawings.

### BRIEF DESCRIPTION OF THE DRAWING FIGURES

FIG. 1 illustrates an exemplary electronic module in accordance with the present invention; and

FIGS. 2a-2h illustrate an exemplary process for forming the electronic module of the present invention.

### DETAILED DESCRIPTION OF THE EMBODIMENTS

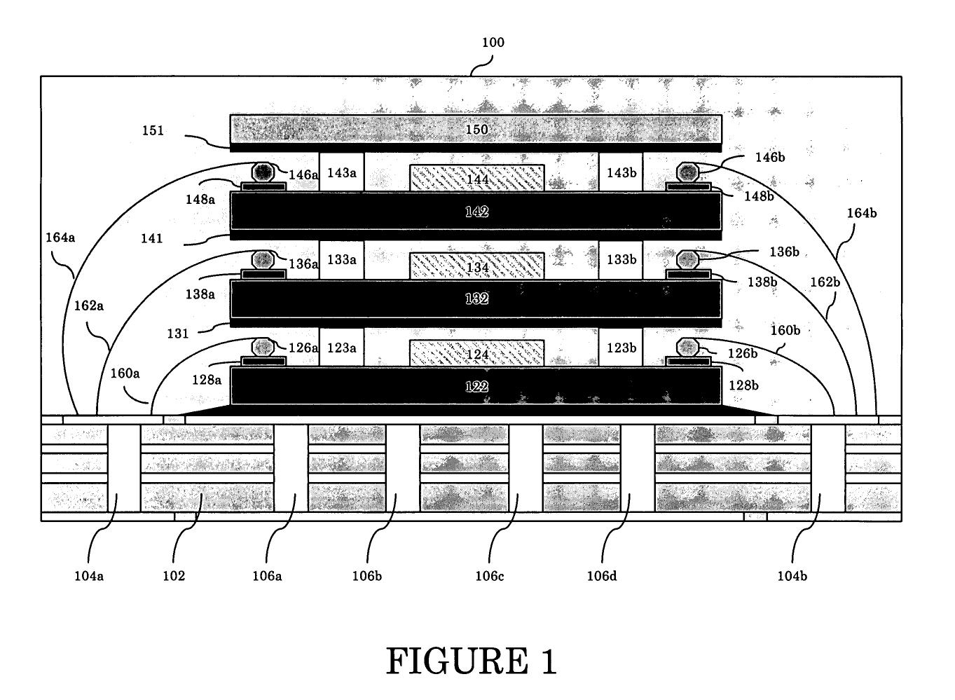

FIG. 1 illustrates an exemplary electronic module 100 in accordance with the present invention. The electronic module 100 includes a substrate 102 and two or more electronic devices, each of which comprise a wafer, active device, contact pads, and gold or copper balls. The substrate 102 includes one or more thermal vias 106a-106d, one or more input/output (I/O) lines 104a and 104b, and integrated transmission lines and inductors. Substrate 102 can be a lead free (LF) laminate or ceramic substrate.

A first electronic device includes a wafer 122, active device 124, gold or copper balls 126a and 126b, and contact pads 128a and 128b. The contact pads 128a and 128b are respectively coupled to the I/O lines 104a and 104b by bonding wires 160a and 160b.

A second electronic device is arranged on spacers 123a and 123b above the first electronic device, thereby forming a uniform and sealed air gap between the first and second electronic devices. Specifically, an adhesive layer 131 couples the spaces 123a and 123b to the second electronic device. The second electronic device includes a wafer 132, active device 134, gold or copper balls 136a and 136b, and contact pads 138a and 138b. The contact pads 138a and 138b are respectively coupled to the I/O lines 104a and 104b by bonding wires 162a and 162b.

Module 100 also includes a third electronic device arranged above the second electronic device on spacers 133a and 133b. Specifically, spacers 133a and 133b are provided on wafer 132 of the second electronic device and the third electronic device is coupled to the spacers 133a and 133b by an adhesive layer 141. The third electronic device includes an active device 144 and contact pads 148a and 148b on wafer 142. Gold or copper balls 146a and 146b are respectively coupled to bonding wires 164a and 164b, which in turn are coupled to I/O lines 104a and 104b, respectively.

A lid 150 is arranged above the uppermost electronic device, which in the illustrated embodiment is the third electronic device. Lid 150 can be composed of silicon, glass, ceramic or the like material. Lid 150 includes an adhesive layer 151 on the side facing the third electronic device. Spacers 143a and 143b are arranged on wafer 142 of the third electronic device and are coupled to the adhesive layer 151.

Although FIG. 1 illustrates an electronic module with three electronic devices, the electronic module can have more or less than three electronic devices. Active devices 124, 134 and 144 can be integrated circuits or microelectronic machines (MEMS). For example, in a radio frequency module, active devices 134 and 144 can be a transmitter and receiver filter, and active device 124 can be a switch. In a radio frequency module, I/O lines 104a and 104b can be coupled to an antenna, such as a low-gain antenna. In accordance with exemplary embodiments of the present invention, the spacers can be composed of polymer and have dimensions between 30 and 200 μm wide, and between 10 and 200 μm high. When the active devices 124, 134 and 144 are radio frequency devices, the height of the spacers and the resulting uniform and sealed air gap are selected to minimize interference between the active devices. In the case of microelectronic machines, the height of the spacers and the resulting uniform and sealed air gap are selected to provide sufficient clearance for the operation of the microelectronic machines.

Arranging the various electronic devices vertically reduces the costs of the resulting electronic module, as the electronic devices share the same I/O line, and only one lid is required for all of the electronic devices. Additionally, the vertically arrangement can significantly reduce the X and Y dimensions, saving precious circuit board space and minimizing interconnect lengths and inductances. Moreover, the electronic module of the present invention can be pre-tested as a discrete component, thereby lowering the bill of materials and assembly costs, and providing a pre-testable component that can be sold to device manufacturers.

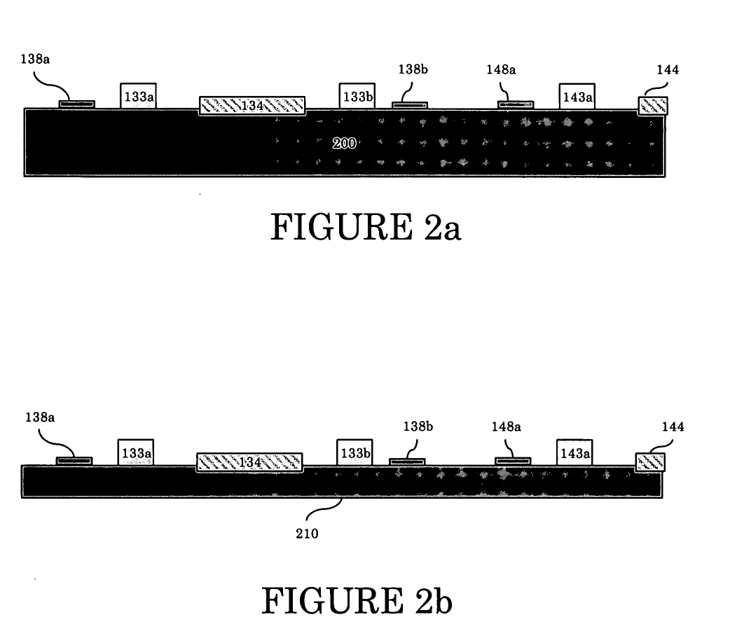

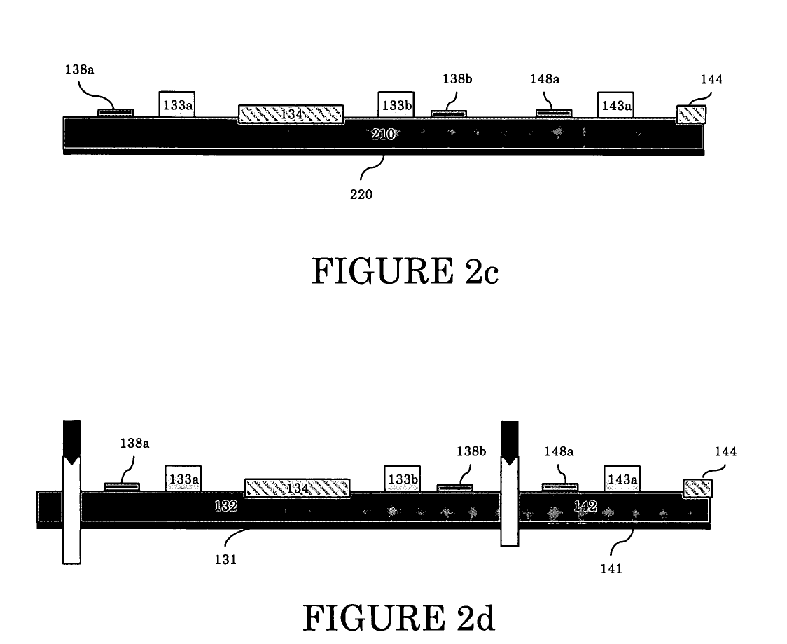

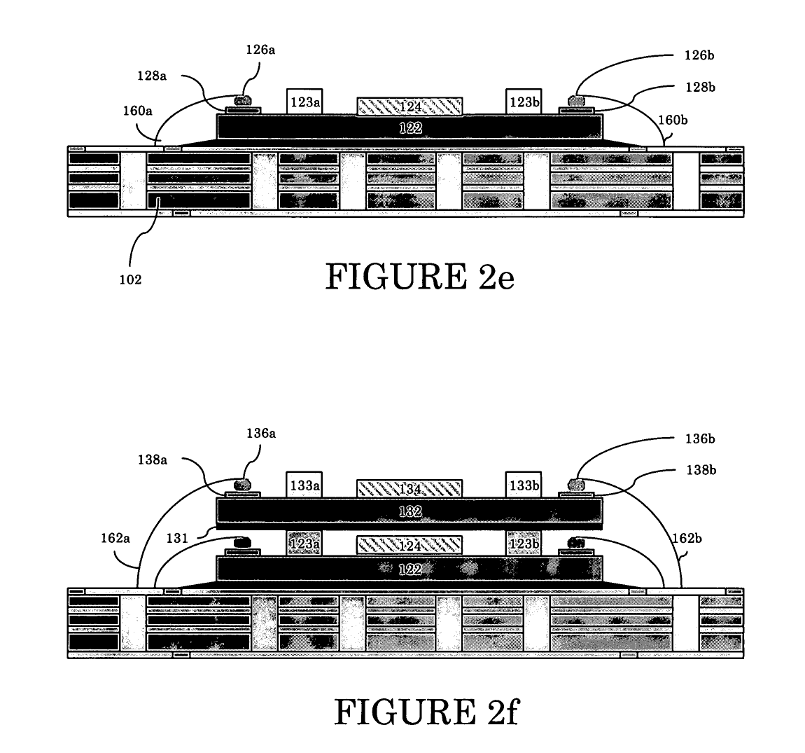

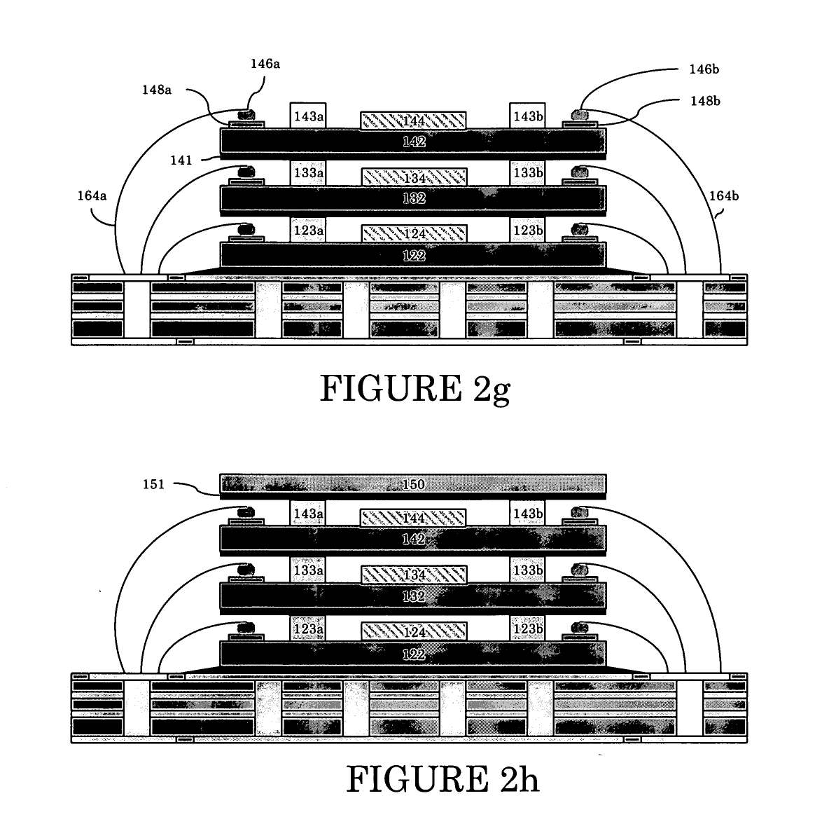

Now that an overview of the electronic module has been presented, a process of manufacturing the electronic module will be described in connection with FIGS. 2a-2h. The process involves a wafer 200 with one or more active devices 134 and 144, and corresponding contact pads. For each active device, two or more spacers 133a and 133b are arranged on the wafer 200 by spin or spray coating, and photo development or screen printing (FIG. 2a). Since wafer 200 includes a second active device 144, a second set of spacers 148a and 148b (not illustrated) are formed on the wafer. A set of spaces can be formed for each active device upon which another active device will be stacked in the electronic module.

Next the device wafer is thinned from a full wafer thickness to a thickness between 50 and 200 μm using any conventional semiconductor back lapping process to form wafer 210 (FIG. 2b). As illustrated in FIG. 2c, an adhesive 220, such as a B-stage adhesive film, is formed on the side of the wafer 210 opposite to the active devices 134 and 144, using, for example, a lamination or coating process. Next, the individual electronic devices are formed by a die singulation process (FIG. 2d).

As illustrated in FIG. 2e, the first electronic device, with the first active device 124, is attached to substrate 102 using conventional die placement equipment. Spacers 123a and 123b are formed by spin or spray coating, and photo development or screen printing. Bonding wires 160a and 160b are respectively placed on gold or copper balls 126a and 126b, and on I/O lines 104a and 104b. The gold or copper balls 126a and 126b are heated, thereby mechanically and electrically coupling contact pads 128a and 128b to I/O lines 104a and 104b, respectively. Next, the second electronic device is arranged above the first electronic device in such a way that the adhesive on the bottom of the second electronic device mates with the spacers 123a and 123b (FIG. 2f). The second electronic device is wire bonded to the I/O lines 104a and 104b in a similar manner to that described above in connection with the first electronic device. As illustrated in FIG. 2g, the third electronic device is arranged above the second electronic device in a similar manner to that described above in connection with the second electronic device, and the third electronic device is wire bonded to the I/O lines 104a and 104b.

Lid 150 is arranged above the uppermost electronic device, which in the present description is the third electronic device, with adhesive layer 151 adjoining spacers 143a and 143b (FIG. 2h). After the lid has been attached, the entire module is heated to a predetermined temperature (e.g., 150° C.) in a controlled environment for a predetermined amount of time (e.g., 1 hour) to cure the adhesive. The entire module is then encapsulated to form the electronic module illustrated in FIG. 1.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. An electronic module, comprising:
a substrate;
a first electronic device arranged on the substrate;
a second electronic device arranged above the first electronic device; and
an air gap between the first and second electronic devices.

2. The electronic module of claim 1, further comprising:
a spacer arranged between the first and second electronic devices, which defines a vertical height of the air gap.

3. The electronic module of claim 2, wherein the spacer is composed of polymer.

4. The electronic module of claim 1, wherein an adhesive layer is arranged on a side of the second electronic device facing the first electronic device.

5. The electronic module of claim 1, wherein the first and second electronic devices include integrated circuits.

6. The electronic module of claim 5, wherein the integrated circuits are radio frequency integrated circuits.

7. The electronic module of claim 6, wherein the first and second electronic modules are filters.

8. The electronic module of claim 1, further comprising:
a third electronic device arranged above the second electronic device; and
an air gap between the second and third electronic devices.

9. The electronic module of claim 8, wherein the first, second and third electronic devices include active devices, and the active device of the first electronic device is a switching device and the active devices of the second and third electronic devices are filters.

10. The electronic module of claim 1, wherein the first and second electronic devices include microelectronic machines.

11. The electronic module of claim 1, further comprising:
a lid arranged above the second electronic device; and air gap between the lid and the second electronic device.

12. The electronic module of claim 11, wherein the lid is composed of silicon, glass or ceramic.

13. A process for manufacturing an electronic module, comprising the steps of:
providing a first electronic device;
preparing a spacer on the first electronic device; and
arranging a second electronic device on the spacer, thereby forming an air gap between the first and second electronic devices.

14. The process of claim 13, further comprising the step of:
forming an adhesive layer on a side of the second electronic device facing the first electronic device prior to arranging the second electronic device on the spacer.

15. The process of claim 13, further comprising the step of:
wire bonding the first and second electronic devices.

16. The process of claim 13, wherein the step of preparing a spacer on the first electronic device comprises preparing a spacer on the second electronic device, and the process further comprises the step of:
arranging a lid on the spacers prepared on the second electronic device, thereby forming an air cavity between the lid and the second electronic device.

17. The process of claim 16, further comprising the step of:
heating the module for a predetermined amount of time to cure the spacers.

18. The process of claim 13, wherein the step of preparing a spacer on the first electronic device comprises preparing a spacer on the second electronic device, the process further comprising the steps of:
forming an adhesive on a side of a third electronic device facing the second electronic device; and
arranging the side of the third electronic device with the adhesive on the spacer on the second electronic device.

19. The process claim 13, wherein the first and second electronic devices are formed on a same wafer, and the process further comprising the steps of:
separating the wafer to form the first and second electronic devices, wherein the spacer is prepared on the first electronic device prior to separating the first and second electronic devices.

20. The process of claim 13, wherein the first and second electronic devices include integrated circuits.

21. The process of claim 20, wherein the integrated circuits are radio frequency integrated circuits.

22. The process of claim 13, wherein the first and second electronic devices include microelectronic machines.
